(19) United States
(12) Patent Application Publication
(10) Pub. No.: US 2006/0202233 A1
(43) Pub. Date: Sep. 14, 2006

(54) Semiconductor device and manufacturing method thereof

(75) Inventor: Akito Hara, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/167,580

(22) Filed: Jun. 28, 2005

(30) Foreign Application Priority Data
Feb. 28, 2005 (JP) 2005-054629

(51) Int. Cl. H01L 29/76

(52) U.S. Cl. 257/213

(57) ABSTRACT

A semiconductor device is disclosed. The semiconductor device includes a semiconductor layer having a channel region, a strain generating layer to cause strain in the channel region by applying a stress to the channel region, a gate insulating film formed on the channel region, and a gate electrode formed on the gate insulating film. An impurity region containing nitrogen, oxygen, or boron as impurities is provided in the semiconductor layer or the strain generating layer.

### BACKGROUND OF THE INVENTION

1. Field of the Invention

The present invention relates to a semiconductor device and a manufacturing method thereof.

2. Description of the Related Art

FETs (Field Effect Transistor) have a characteristic in that strain in channel regions improves carrier mobility. This characteristic becomes more pronounced as element regions become more compact. Therefore, “strain generating techniques” for causing strain in channel regions are attracting increased interest for application to super speed FETs having a gate length of 100 nm or less. FIG. 1 illustrates an example of strain generating methods. According to this method, a Si (silicon) layer having an N-channel region is formed on the surface of a SiGe (silicon-germanium) layer. Thus, a biaxial tensile stress is applied to the N-channel to cause strain therein. FIG. 2 illustrates another example of strain generating methods. According to this method, SiGe layers are embedded into a Si layer. Thus, a uniaxial compressive stress is applied to a P-channel region to cause strain therein (see Reference 1: A. Shimizu et al., Tech. Dig. of 2001 IEDM, IEEE, 2001, pp. 443-436, and Reference 2: K. Goto et al., Tech. Dig. of 2004 IEDM, IEEE, 2004, pp. 209-212). In these strain generating methods, the difference between the Si lattice constant and the SiGe lattice constant is a factor in generating a stress.

When a crystal as shown in FIG. 3A is strained as shown in FIG. 3B, dislocation (FIG. 3C) is activated and expanded in the crystal under high temperature and high stress conditions. The term “dislocation” indicates linear crystal defects. The types of dislocation include edge dislocation and screw dislocation. When the dislocation is activated and expanded in the strained crystal, the strain in the crystal is relieved by the dislocation.

The dislocation is not caused by self-nucleation. There is always a source that causes initial dislocation. In the case of the strain generating method of FIG. 1, the dislocation source may be, for example, through migration that has occurred when the SiGe layer or the Si layer is formed. In the case of the strain generating method of FIG. 2, the dislocation source may be, for example, a lattice defect due to etching damage caused when grooves for layer embedment are formed. When the wafer is processed at high temperature, the initial dislocation is activated in the Si layer or the SiGe layers and expanded in the Si layer or the SiGe layers. The dislocation thus relieves the strain in the channel region, thereby lowering the strain effect in the channel region for carrier mobility enhancement.

### SUMMARY OF THE INVENTION

A general object of the present invention is to provide a semiconductor device to solve at least one problem described above. A specific object of the present invention is to provide a semiconductor device having a strained channel region capable of preventing lowering of a strain effect in the channel region for carrier mobility enhancement.

To achieve these and other advantages and in accordance with the purpose of the present invention, as embodied and broadly described herein, there is provided a semiconductor device that includes a semiconductor layer having a channel region, a strain generating layer to cause strain in the channel region by applying a stress to the channel region, a gate insulating film formed on the channel region, and a gate electrode formed on the gate insulating film, wherein an impurity region containing nitrogen, oxygen, or boron as impurities is provided in the semiconductor layer or the strain generating layer.

There is also provided a manufacturing method of a semiconductor device that comprises the steps of generating a strain generating layer that causes strain in a channel region in a semiconductor layer by applying a stress to the channel region, forming a gate insulating film on the channel region, forming a gate electrode on the gate insulating film, and forming an impurity region containing nitrogen, oxygen, or boron as impurities in the semiconductor layer or the strain generating layer.

### BRIEF DESCRIPTION OF THE DRAWINGS

FIG. 1 shows a cross-sectional view of a semiconductor device formed by a strain generating method of causing strain in a channel region by application of a biaxial tensile stress;

FIG. 2 shows a cross-sectional view of a semiconductor device formed by a strain generating method of causing strain in a channel region by application of a uniaxial compressive stress;

FIGS. 3A-3C show schematic cross-sectional views of a crystal for illustrating dislocation;

FIG. 4 shows a cross-sectional view of a semiconductor device according to a first embodiment;

FIGS. 5A-5E show cross-sectional views of a semiconductor device for illustrating a manufacturing method thereof according to the first embodiment;

FIG. 6 is a graph showing a relationship between presence of impurities and a dislocation locking effect;

FIG. 7 is a table showing a relationship between impurity concentration and a dislocation locking effect;

FIG. 8 shows a cross-sectional view of a semiconductor device according to a second embodiment;

FIGS. 9A-9E are cross-sectional views of a semiconductor device for illustrating a manufacturing method thereof according to the second embodiment;

FIG. 10 shows a cross-sectional view of a semiconductor device for illustrating impurity regions according to the first embodiment; and

FIG. 11 shows a cross-sectional view of a semiconductor device for illustrating impurity regions according to the second embodiment.

### DETAILED DESCRIPTION OF THE PREFERRED EMBODIMENT

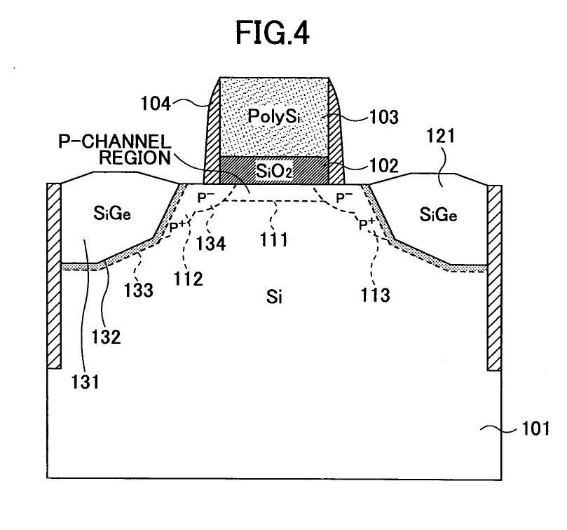

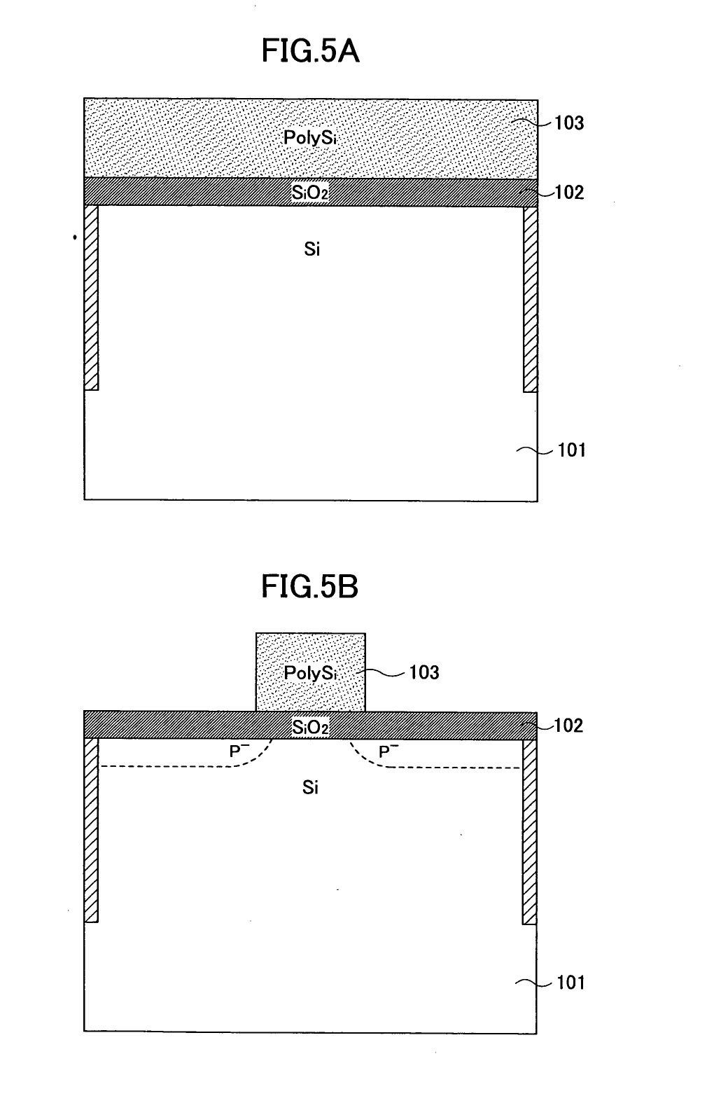

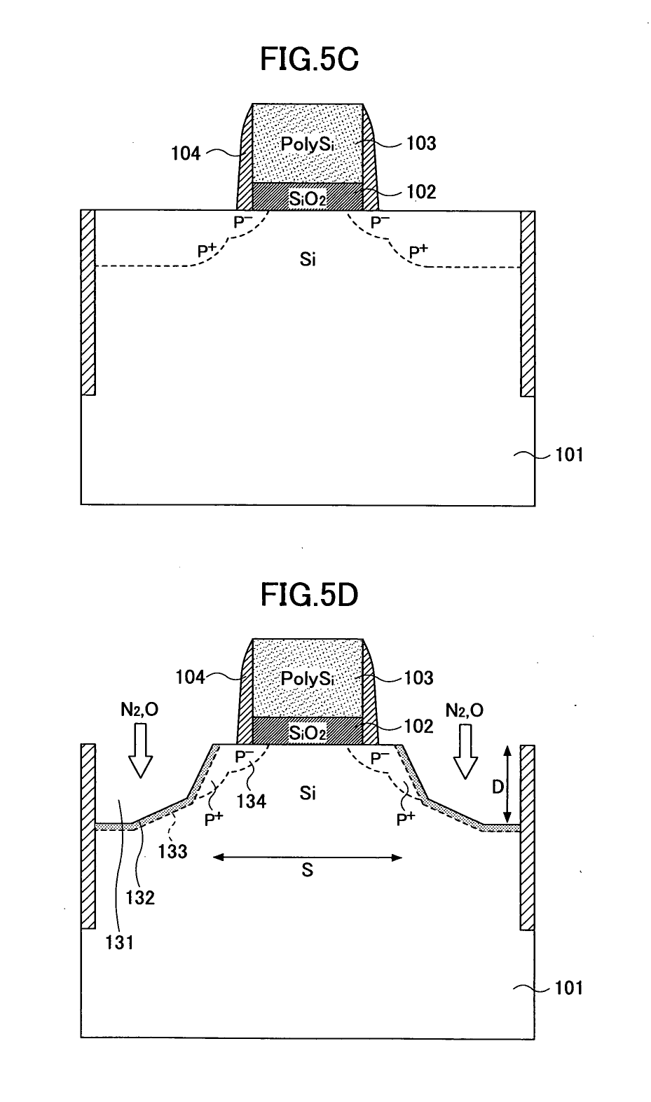

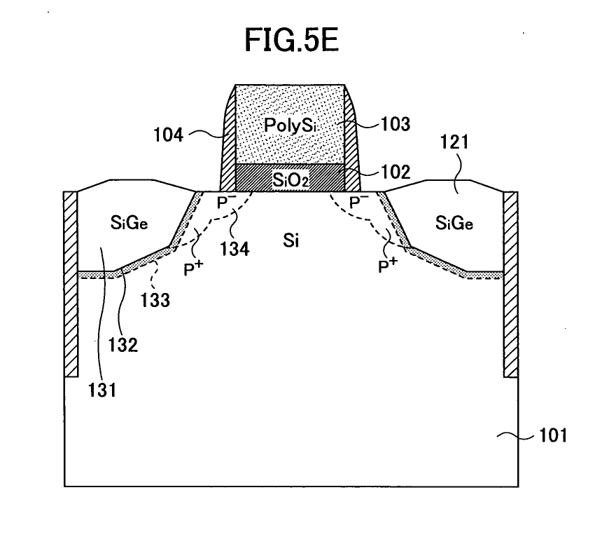

FIG. 4 shows a cross-sectional view of a semiconductor device according to a first embodiment, and FIGS. 5A-5E show cross-sectional views of a semiconductor device for illustrating a manufacturing method thereof according the first embodiment. In the first embodiment, a semiconductor device having a MOSFET as a semiconductor element is fabricated.

The semiconductor device shown in FIG. 4 comprises a semiconductor substrate 101, a gate insulating film 102, a gate electrode 103, and a sidewall 104. The semiconductor substrate 101 includes a channel region 111, a source region 112, and a drain region 113.

The semiconductor device of FIG. 4 further comprises strain generating layers 121 that cause strain in the channel region 111 by applying a uniaxial compressive stress thereto. The strain generating layers 121 are embedded in grooves 131 formed one in each of the source region 112 and the drain region 113 to be in contact with the semiconductor substrate 101. The semiconductor substrate 101 is made of Si, while the strain generating layers 121 are made of SiGe. The difference between the Si lattice constant and the SiGe lattice constant is a factor of generating the uniaxial compressive stress. In the case where the channel region 111 is a P-channel, the strain generating layer 121 of SiGe is generally provided. On the other hand, in the case where the channel region 111 is an N-channel, the strain generating layer 121 of SiC (silicon carbide) is generally provided.

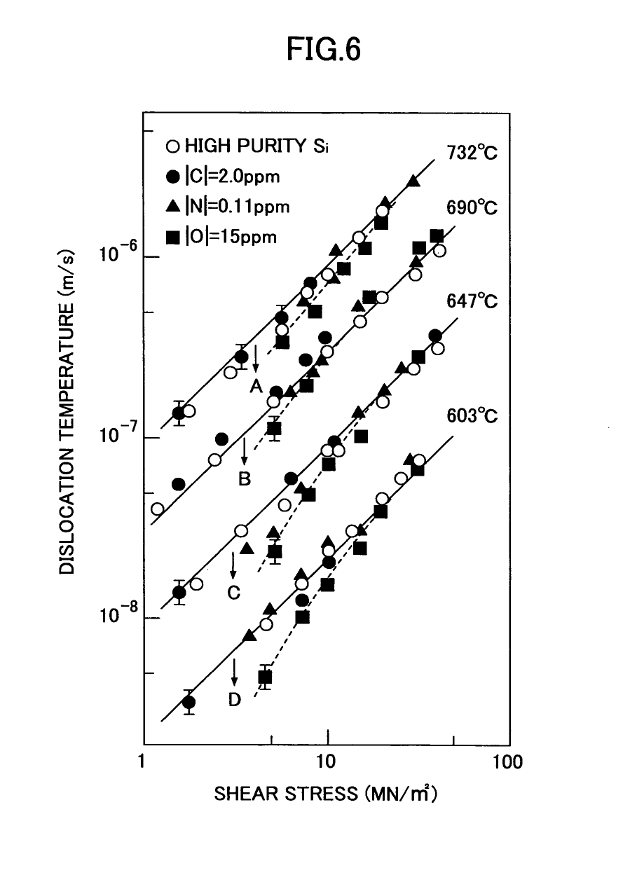

The semiconductor device of FIG. 4 further comprises impurity regions 133 each formed in the vicinity of corresponding interfaces 132 between the semiconductor substrate 101 and the strain generating layers 121. The impurity regions 133 contain nitrogen, oxygen, or boron as impurities. It is known that nitrogen, oxygen, and boron have a high effect of reducing the dislocation motion velocity (i.e., a high dislocation locking effect). FIG. 6 is a graph showing results of an experiment (cited from Reference 3: “Research Report on Control of Material Function Utilizing Semiconductor Lattice Defect” 1986, The Society of Non-Traditional Technology, pp. 67-81). Comparing the dislocation motion velocity with and without the presence of nitrogen or oxygen under the same temperature and stress condition, it is found that the dislocation motion velocity is reduced when nitrogen or oxygen is present as indicated by arrows A, B, C, and D. Accordingly, if the impurity regions 133 are formed on or in the semiconductor substrate 101 and the strain generating layers 121, initial dislocation in the semiconductor substrate 101 and the strain generating layers 121 is locked, thereby preventing activation and expansion of dislocation in the semiconductor substrate 101 and the strain generating layers 121. For this reason, the impurity regions 133 are provided in the vicinity of the interfaces 132 between the semiconductor substrate 101 and the strain generating layers 121 in this embodiment. The lowering of a strain effect in the channel region 111 for carrier mobility enhancement is thus prevented.

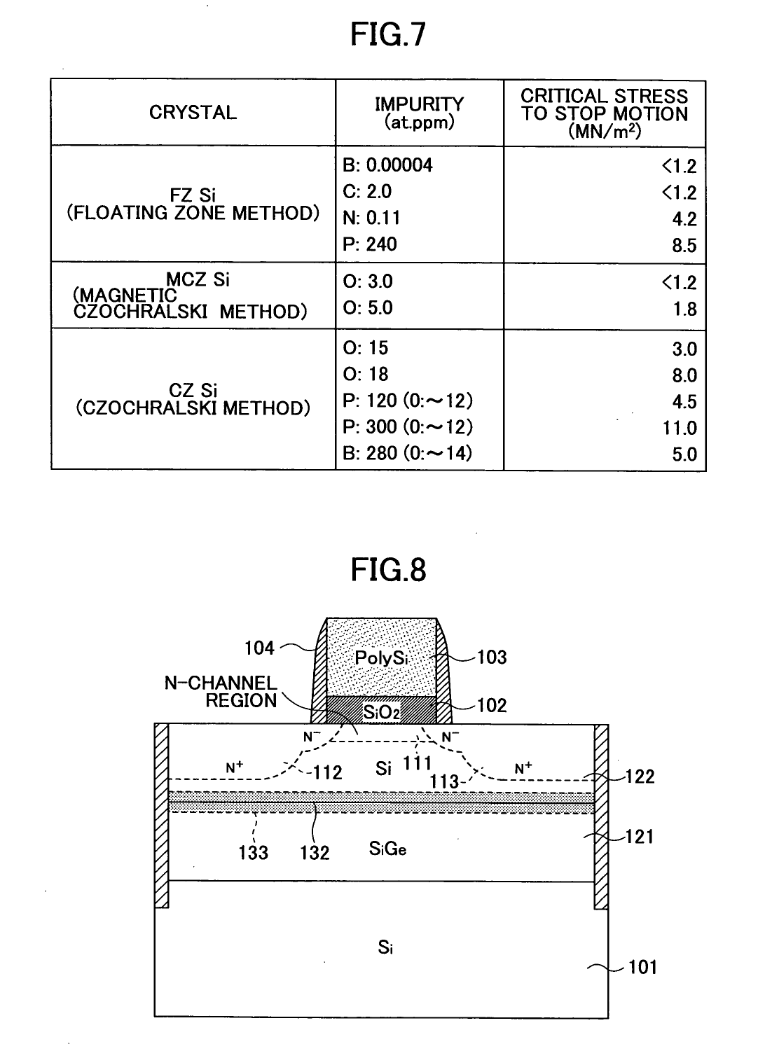

In the case where nitrogen is employed as the impurities, the concentration of the nitrogen impurities in the impurity regions 133 is set to 1.0×10¹⁵ cm⁻³ through 1.0×10¹⁷ cm⁻³. In the case where oxygen is employed as the impurities, the concentration of the oxygen impurities in the impurity regions 133 is set to 2.5×10¹⁷ cm⁻³ through 1.0×10¹⁹ cm⁻³. In the case where boron is employed as the impurities, the concentration of the boron impurities in the impurity regions 133 is set to 1.0×10¹⁸ cm⁻³ through 1.0×10²⁰ cm⁻³. If the concentration exceeds the upper limit, the silicon gets nitrided to become silicon nitride, or gets oxidized to become silicon oxide. FIG. 7 is a table showing results of another experiment (cited from Reference 3). It is found from the experiment that the concentration of the impurities that can achieve a critical stress to stop motion (dislocation motion is stopped when the stress equals to or falls below criticality) is 0.11 ppm substantially corresponding to 5.5×10¹⁵ cm⁻³ in the case of nitrogen impurities, and is 5.0 ppm substantially corresponding to 2.5×10¹⁷ cm⁻³ in the case of oxygen impurities. The nitrogen impurities, the oxygen impurities, and the boron impurities in the impurity regions 133 exist in the form of molecular nitrogen N₂, oxygen atoms O, and boron atoms B (or interstitial atoms B), respectively. The impurity regions 133 may contain only one of the above three types of impurities or may contain two or three of the above.

The following describes the manufacturing method of the semiconductor device of FIG. 4 with reference to FIGS. 5A-5E.

First, referring to FIG. 5A, a SiO₂ (silicon oxide) film 102 having a thickness of 2 nm is deposited on a surface of the semiconductor substrate 101 of Si by a thermal oxidation process. A PolySi (polysilicon) layer 103 having a thickness of 100 nm is deposited on a surface of the SiO₂ film 102 by a CVD process. Then, referring to FIG. 5B, the gate electrode 103 of PolySi is formed by a dry etching process. Subsequently, P⁻ regions (source/drain regions) are formed inside the semiconductor substrate 101 by an ion implantation process.

Then, referring to FIG. 5C, the gate insulating film 102 of SiO₂ and the sidewall 104 of SiN are formed by an etch back process. Subsequently, P⁺ regions (source/drain regions) are formed inside the semiconductor substrate 101 by an ion implantation process.

Then, referring to FIG. 5D, the grooves 131 are formed by a dry etching process in the source/drain regions. The depth (D in FIG. 5D) of the grooves 131 is around 50 nm, and the interval (S in FIG. 5D) between the grooves 131 is around 200 nm. The impurity regions 133 are formed in the vicinity of corresponding surfaces 132 of the grooves 131 by an ion implantation process. The thickness of the impurity regions 133 is 10 through 40 nm, and the concentration of the impurities in the impurity regions 133 is 5.0×10¹⁶ cm⁻³ in the case of N₂, and 3.0×10¹⁸ cm⁻³ in the case of O. The ion implantation energy is around 10 through 40 KeV (5 KeV for extension regions 134). Subsequently, an annealing process is performed for restoring etching damage and implantation damage, and for locking lattice defects and initial dislocation. The annealing process is performed using an RTA at 800 through 1000° C. for predetermined seconds. Then, referring to FIG. 5E, SiGe layers 121 are embedded into the grooves 131 by a CVD process to form the strain generating layers 121 of SiGe.

According to the first embodiment, as shown in FIG. 10, the impurity regions 133 are formed in the vicinity (on the semiconductor substrate 101 side) of the interfaces 132 between the semiconductor substrate 101 and the strain generating layers 121. The initial source of dislocation in the first embodiment is lattice defects or dislocation loops (FIG. 2) due to etching damage caused when the grooves 131 are formed. Because there is a possibility that the lattice defects and the dislocation loops may occur anywhere in the vicinity (on the semiconductor substrate 101 side) of the interfaces 132, the impurity regions 133 are formed throughout the vicinity (the semiconductor substrate 101 side) of the interfaces 132 in the first embodiment.

If the dislocation propagates to the channel region 111, the propagated dislocation relieves the strain in the channel region 111. This lowers the strain effect in the channel region 111 for carrier mobility enhancement. Or, a gate leakage current is increased. As can be seen, dislocation considered to be problematic in the first embodiment is the dislocation trying to propagate to the channel region 111. Accordingly, a part where formation of the impurity regions 133 is most required in the vicinity of the interfaces 132 is regions H (FIG. 10) located at the same horizontal position as horizontal to the channel region 111. This is because the regions H are closest to the channel region 111.

The impurities contained in the impurity regions 133 are diffused in the SiGe layers 121 in a subsequent SiGe layer growth process so as to lock dislocation occurrence and expansion in the SiGe layers 121. If the dislocation propagates to the SiGe layers 121, the propagated dislocation relieves the strain in the channel region 111. Therefore, locking the dislocation in the SiGe layers 121 is also an important effect of the impurities contained in the impurity regions 133.

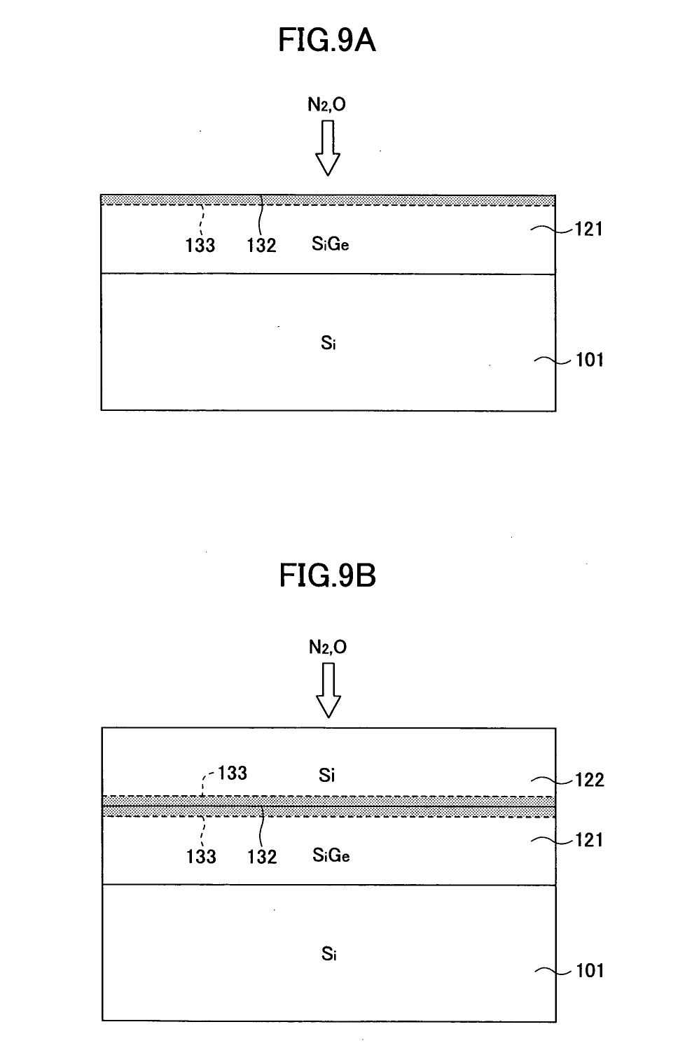

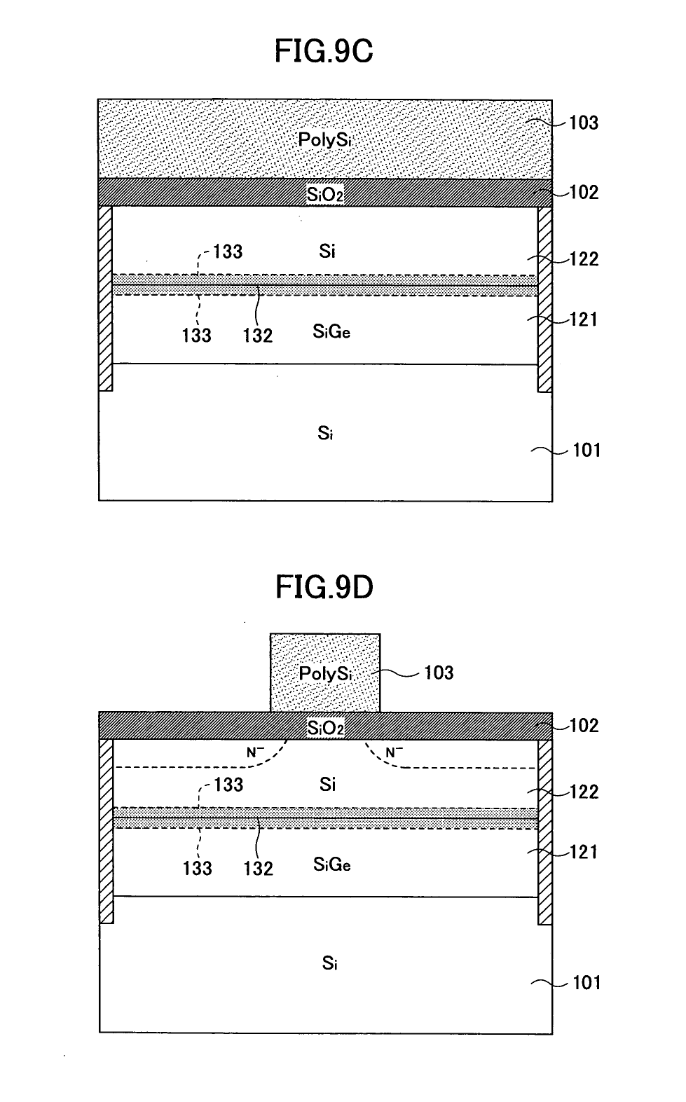

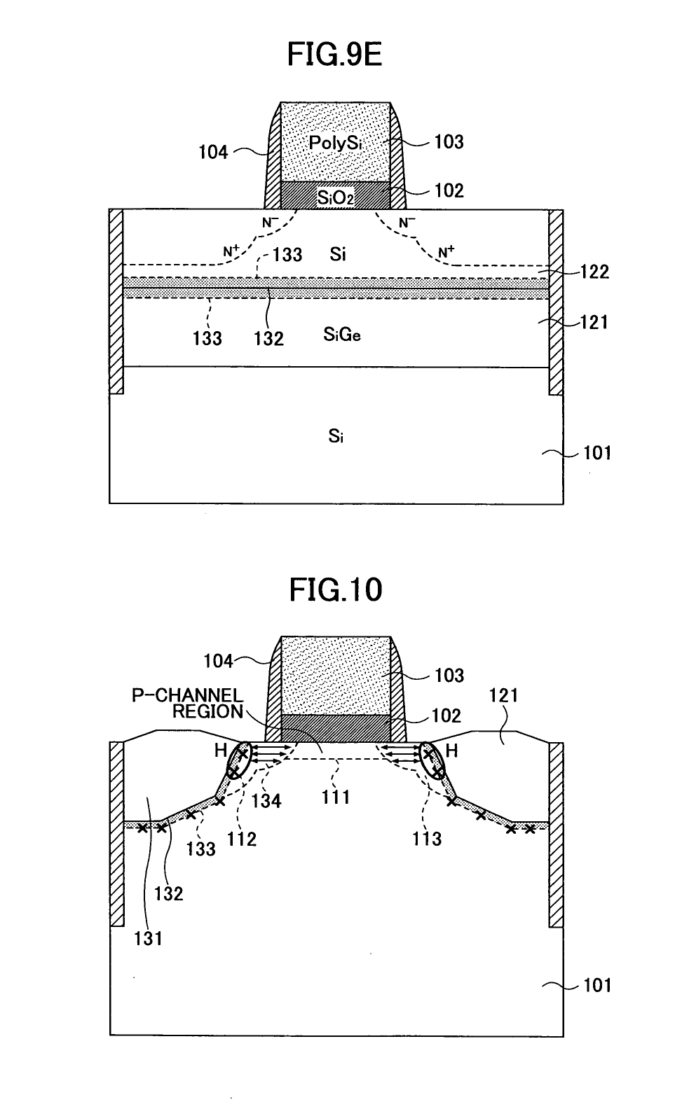

FIG. 8 shows a cross-sectional view of a semiconductor device according to a second embodiment, and FIGS. 9A-9E show cross-sectional views of a semiconductor device for illustrating a manufacturing method thereof according the second embodiment. In the second embodiment, a semiconductor device having a MOSFET as a semiconductor element is fabricated.

The semiconductor device shown in FIG. 8 comprises a semiconductor substrate 101, a gate insulating film 102, a gate electrode 103, and a sidewall 104.

The semiconductor device of FIG. 8 further comprises a semiconductor layer 122 that includes a channel region 111, a source region 112, a drain region 113, and a strain generating layer 121 that causes strain in the channel region 111 by applying a biaxial tensile stress thereto. The strain generating layer 121 lies under the semiconductor layer 122 to be in contact therewith. The semiconductor layer 122 is made of Si, while the strain generating layer 121 is made of SiGe. The difference between the Si lattice constant and the SiGe lattice constant is a factor of generating the biaxial tensile stress. In the case where the channel region 111 is an N-channel, the strain generating layer 121 of SiGe of a tensile type is generally provided. On the other hand, in the case where the channel region 111 is an N-channel, the strain generating layer 121 of SiC of a compressive type is generally provided.

The semiconductor device of FIG. 8 further comprises impurity regions 133 formed in the vicinity of an interface 132 between the semiconductor layer 122 and the strain generating layer 121. The impurity regions 133 contain nitrogen or oxygen as impurities. This is the same as in the semiconductor device of FIG. 4.

In the case where nitrogen is employed as the impurities, the concentration of the nitrogen impurities in the impurity regions 133 is set to 1.0×10¹⁵ cm⁻³ through 1.0×10¹⁷ cm⁻³. In the case where oxygen is employed as the impurities, the concentration of the oxygen impurities in the impurity regions 133 is set to 2.5×10¹⁷ cm⁻³ through 1.0×10¹⁹ cm⁻³. This is the same as in the semiconductor device of FIG. 4.

The following describes the manufacturing method of the semiconductor device of FIG. 8 with reference to FIGS. 9A-9E.

First, referring to FIG. 9A, a SiGe layer 121 having a thickness of 1 μm is deposited on a surface of the semiconductor substrate 101 of Si by a CVD process to form the strain generating layer 121 of SiGe. In this step, the impurity region 133 is formed inside the strain generating layer 121 by an ion implantation process. The impurity region 133 in the strain generating layer 121 has a thickness of 10 through 40 nm. The concentration peak of the impurities in the impurity region 133 in the strain generating layer 121 is 5.0×10¹⁶ cm⁻³ in the case of N₂, and 3.0×10¹⁸ cm⁻³ in the case of O. The ion implantation energy to the strain generating layer 121 is around 10 through 40 KeV.

Then, referring to FIG. 9B, a Si layer 122 having a thickness of tens of nanometers is deposited on the surface of the strain generating layer 121 by a CVD process to form the semiconductor layer 122 of Si. In this step, the impurity region 133 is formed inside the semiconductor layer 122 by an ion implantation process. The impurity region 133 in the semiconductor layer 122 has a thickness of 10 nm. The concentration peak of the impurities in the impurity region 133 in the semiconductor layer 122 is 5.0×10¹⁶ cm⁻³ in the case of N₂, and 3.0×10¹⁸ cm⁻³ in the case of O. Subsequently, an annealing process is performed for locking initial dislocation. The annealing process is performed using an RTA at 800 through 1000° C. for predetermined seconds.

Then, referring to FIG. 9C, a SiO₂ film 102 having a thickness of 2 nm is deposited on a surface of the semiconductor layer 122 by a thermal oxidation process. A PolySi layer 103 having a thickness of 100 nm is deposited on a surface of the SiO₂ film 102 by a CVD process. Then, referring to FIG. 9D, the gate electrode 103 of PolySi is formed by a dry etching process. Subsequently, N⁻ regions are formed inside the semiconductor layer 122 by an ion implantation process.

Then, referring to FIG. 9E, the gate insulating film 102 of SiO₂ and the sidewall 104 of SiN are formed by an etch back process. Subsequently, N⁺ regions are formed inside the semiconductor layer 122 by an ion implantation process.

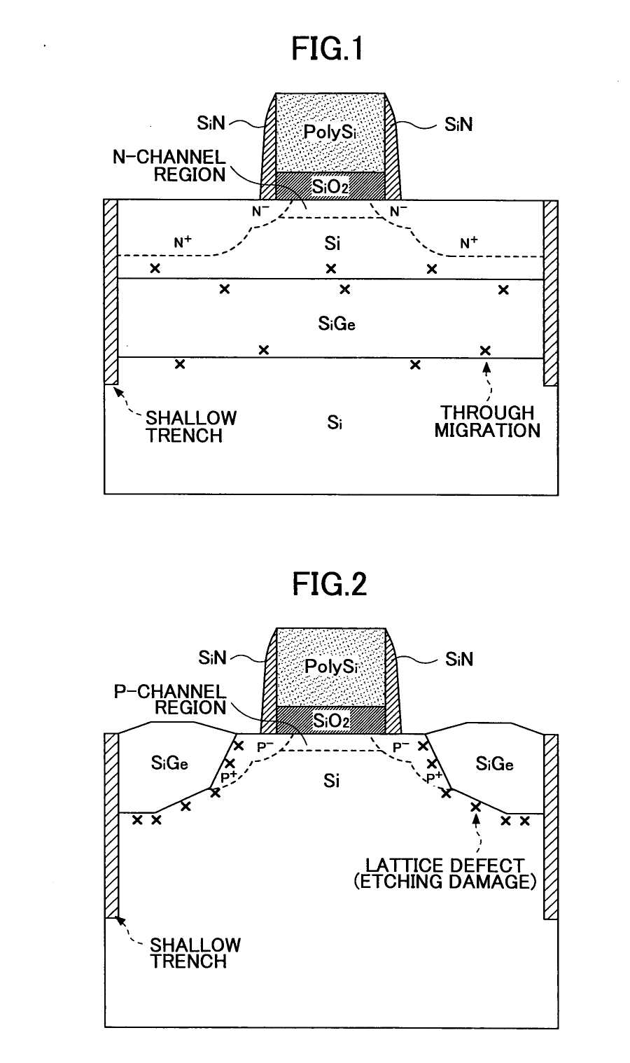

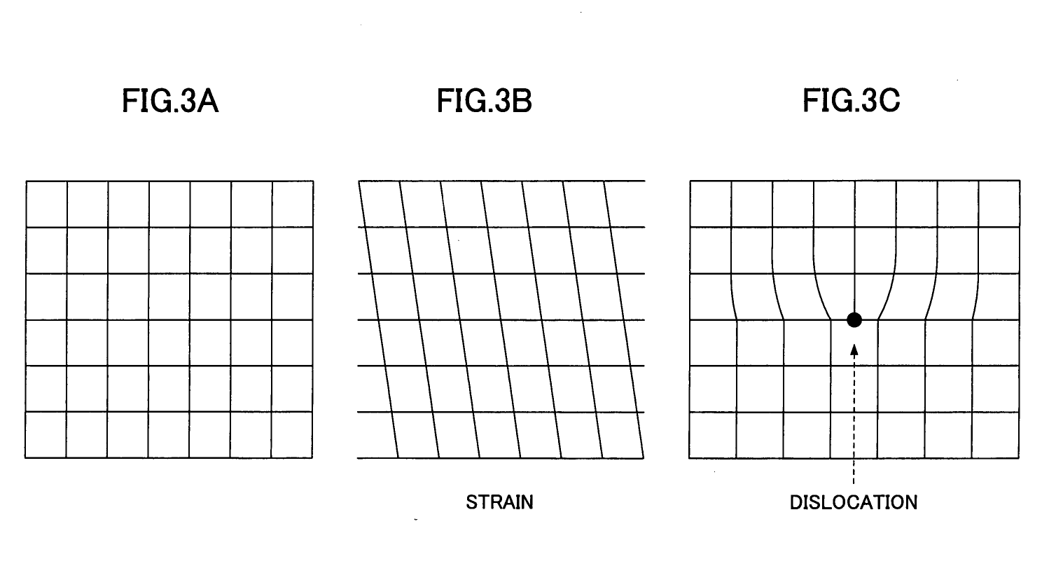

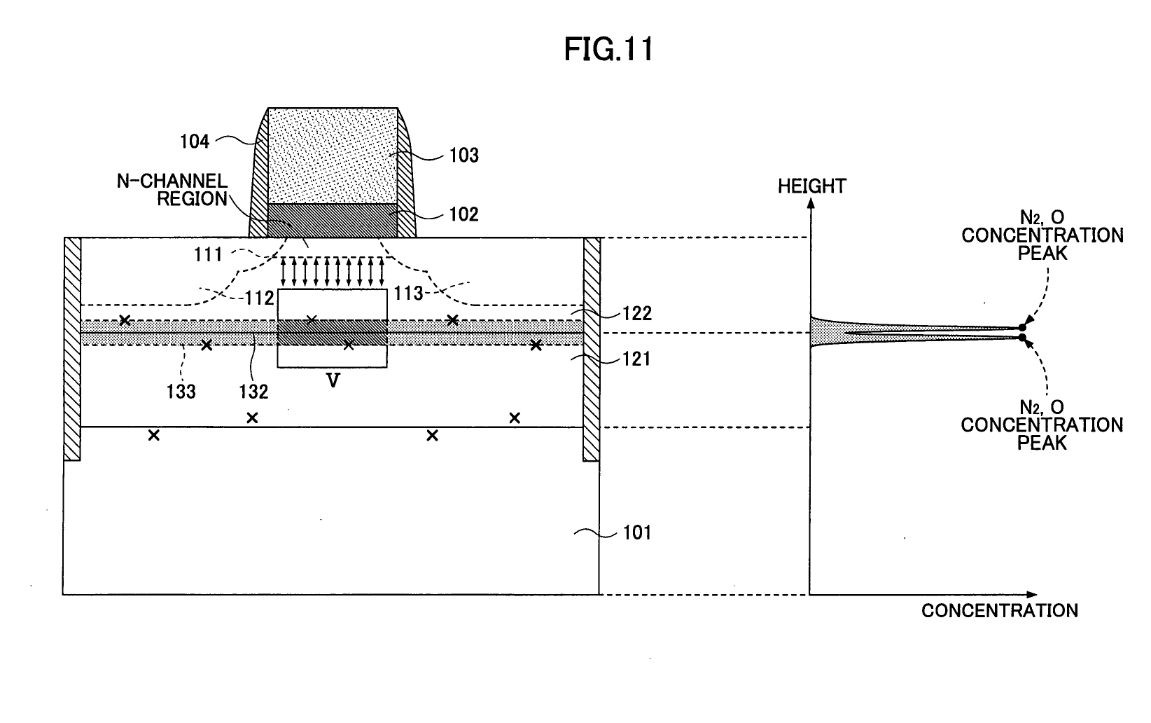

According to the second embodiment, as shown in FIG. 11, the impurity regions 133 are formed in the vicinity of the interface 132 between the semiconductor layer 122 and the strain generating layer 121 (or, inside the semiconductor layer 122 and inside the strain generating layer 121). The initial source of dislocation in the second embodiment is through migration (FIG. 1) caused when the semiconductor layer 122 or the strain generating layer 121 is formed. Because there is a possibility that migration may occur anywhere in the vicinity of the interface 132, the impurity regions 133 are formed throughout the vicinity of the interface 132 in the second embodiment.

If the dislocation propagates to the channel region 111, the propagated dislocation relieves the strain in the channel region 111. This lowers the strain effect in the channel region 111 for carrier mobility enhancement. As can be seen, dislocation considered to be problematic in the second embodiment is the dislocation trying to propagate to the channel region 111. Accordingly, a part where formation of the impurity region 133 is most required in the vicinity of the interface 132 is a region V (FIG. 11) located at the same vertical position as vertical to the channel region 111. This is because the region V is closest to the channel region 111.

The following describes concentration distribution of the impurities in the impurity regions 133.

In the second embodiment, the impurity regions 133 are formed inside the semiconductor layer 122 and the strain generating layer 121. FIG. 11 shows the concentration distribution of the impurities in the impurity regions 133. A concentration peak of the impurities is observed in each of the semiconductor layer 122 and the strain generating layer 121.

The dislocation caused at the semiconductor layer 122 side is mainly locked around the concentration peak inside the semiconductor layer 122. The dislocation caused at the strain generating layer 121 side is mainly locked around the concentration peak inside the strain generating layer 121. Because the dislocation trying to propagate to the channel region 111 is considered to be problematic, the existence of the concentration peak inside the semiconductor layer 122 is more important than the existence of the concentration peak in the strain generating layer 121.

While the concentration peak of the impurities is set in each of the semiconductor layer 122 and the strain generating layer 121 in the second embodiment, the concentration peak may be set in either one of layers 122 or 121. In such a case, it is preferable that the peak be set only in the semiconductor layer 122. While the concentration peak of the impurities is set in each of the semiconductor layer 122 and the strain generating layer 121 in the second embodiment, the concentration peak may be set on the interface 132 between the semiconductor layer 122 and the strain generating layer 121. This is because a high concentration region extends to both the semiconductor layer 122 and the strain generating layer 121.

The above description of the concentration distribution of the impurities in the impurity regions applies not only to the second embodiment but also to the first embodiment.

While the present invention has been described in terms of the above illustrated embodiments, it will be apparent to those skilled in the art that variations and modifications may be made without departing from the scope of the invention as set forth in the accompanying claims.

The present application is based on Japanese Priority Application No. 2005-054629 filed on Feb. 28, 2005, with the Japanese Patent Office, the entire contents of which are hereby incorporated by reference.

What is claimed is:

1. A semiconductor device, comprising:
a semiconductor layer having a channel region;
a strain generating layer to cause strain in the channel region by applying a stress to the channel region;
a gate insulating film formed on the channel region; and
a gate electrode formed on the gate insulating film;
wherein an impurity region containing one or more of nitrogen, oxygen, and boron as impurities is provided in the semiconductor layer or the strain generating layer.

2. The semiconductor device as claimed in claim 1, wherein the impurity region provided in the semiconductor layer or the strain generating layer contains nitrogen as the impurities at a concentration of 1.0×10¹⁵ cm⁻³ through 1.0×10¹⁷ cm⁻³.

3. The semiconductor device as claimed in claim 1, wherein the impurity region provided in the semiconductor layer or the strain generating layer contains oxygen as the impurities at a concentration of 2.5×10¹⁷ cm⁻³ through 1.0×10¹⁹ cm⁻³.

4. The semiconductor device as claimed in claim 1, wherein the impurity region provided in the semiconductor layer or the strain generating layer contains boron as the impurities at a concentration of 1.0×10¹⁸ cm⁻³ through 1.0×10²⁰ cm⁻³.

5. The semiconductor device as claimed in claim 1, wherein a concentration peak of the impurities contained in the impurity region is located on an interface between the semiconductor layer and the strain generating layer.

6. The semiconductor device as claimed in claim 1, wherein a concentration peak of the impurities contained in the impurity region is located inside the semiconductor layer.

7. The semiconductor device as claimed in claim 1, wherein a concentration peak of the impurities contained in the impurity region is located inside the strain generating layer.

8. The semiconductor device as claimed in claim 1, wherein the impurity region is located at the same horizontal position as horizontal to the channel region in the case where the strain is caused in the channel region by applying a uniaxial stress to the channel region.

9. The semiconductor device as claimed in claim 1, wherein the impurity region is located at the same vertical position as vertical to the channel region in the case where the strain is caused in the channel region by applying a biaxial stress to the channel region.

10. The semiconductor device as claimed in claim 1,
wherein the semiconductor layer is made of silicon; and
the strain generating layer is made of silicon and germanium or silicon and carbon.

11. A manufacturing method of a semiconductor device, comprising the steps of:
generating a strain generating layer that causes strain in a channel region in a semiconductor layer by applying a stress to the channel region;
forming a gate insulating film on the channel region;
forming a gate electrode on the gate insulating film; and
forming an impurity region containing one or more of nitrogen, oxygen, and boron as impurities in the semiconductor layer or the strain generating layer.

12. The manufacturing method of a semiconductor device as claimed in claim 11, wherein the impurity region formed in the semiconductor layer or the strain generating layer contains nitrogen as the impurities at a concentration of 1.0×10¹⁵ cm⁻³ through 1.0×10¹⁷ cm⁻³.

13. The manufacturing method of a semiconductor device as claimed in claim 11, wherein the impurity region formed in the semiconductor layer or the strain generating layer contains oxygen as the impurities at a concentration of 2.5×10¹⁷ cm⁻³ through 1.0×10¹⁹ cm⁻³.

14. The manufacturing method of a semiconductor device as claimed in claim 11, wherein the impurity region formed in the semiconductor layer or the strain generating layer contains boron as the impurities at a concentration of 1.0×10¹⁸ cm⁻³ through 1.0×10²⁰ cm⁻³.

15. The manufacturing method of a semiconductor device as claimed in claim 11, wherein a concentration peak of the impurities contained in the impurity region is located on an interface between the semiconductor layer and the strain generating layer.

16. The manufacturing method of a semiconductor device as claimed in claim 11, wherein a concentration peak of the impurities contained in the impurity region is located inside the semiconductor layer.

17. The manufacturing method of a semiconductor device as claimed in claim 11, wherein a concentration peak of the impurities contained in the impurity region is located inside the strain generating layer.

18. The manufacturing method of a semiconductor device as claimed in claim 11, wherein the impurity region is located at the same horizontal position as horizontal to the channel region in the case where the strain is caused in the channel region by applying a uniaxial stress to the channel region.

19. The manufacturing method of a semiconductor device as claimed in claim 11, wherein the impurity region is located at the same vertical position as vertical to the channel region in the case where the strain is caused in the channel region by applying a biaxial stress to the channel region.

20. The manufacturing method of a semiconductor device as claimed in claim 11,
wherein the semiconductor layer is made of silicon; and
the strain generating layer is made of silicon and germanium or silicon and carbon.
